(19) United States
(12) Patent Application Publication
(10) Pub. No.: US 2005/0226050 A1
(43) Pub. Date: Oct. 13, 2005

(54) Apparatus and method for programming flash memory units using customized parameters

(76) Inventor: Robert M. Crosby, Sugar Land, TX (US)

Correspondence Address: TEXAS INSTRUMENTS INCORPORATED, P O BOX 655474, M/S 3999, DALLAS, TX, 75265, US

(21) Appl. No.: 11/088,400

(22) Filed: Mar. 24, 2005

Related U.S. Application Data
(60) Provisional application No. 60/555,935, filed on Mar. 24, 2004.

(51) Int. Cl. G11C 11/34

(52) U.S. Cl. 365/185.18

(57) ABSTRACT

A Flash memory unit has two portions, a first portion having normal Flash memory cells and a second portion having Flash memory cells that are not available to the user. The second Flash memory portion includes data that is used to control the operating parameters, such as voltage levels, of the first Flash memory portion. With these parameters available, the operation of the first Flash memory portion can accommodate changed in the fabrication of the Flash memory unit, whether intentional of unintentional.

This application claims priority under 35 USC §119(e) (1) of Provisional Application No. 60/555,935 (TI-38162PS) filed Mar. 24, 2004.

### BACKGROUND OF THE INVENTION

1. Field of the Invention

This invention relates generally to data processing systems and, more particularly, to the storage of data in Flash memory units.

2. Background of the Invention

The Flash memory, having the advantage of being a programmable read only memory from which data can be erased and data can be written has found increasing application in modern electrical apparatus. The Flash memory has three modes of operation: an erase mode, a write mode, and a read mode.

Referring to FIG. 1, a block diagram of a typical Flash memory cell 10 is shown. A source region 14 and a drain region 15 are fabricated in a p-well 13. A floating gate 12 is fabricated above a well region 13 and with a control gate 11, controls the current flow between the source region 14 and drain region 15. A control gate 11 is used to control the amount of charge on the floating gate 12 during erase or program operations.

Referring to FIG. 2, typical voltages associated with the various modes of the Flash memory cell are illustrated. The modes include the normal read mode, the program (write) mode and the erase mode. In addition, the Flash memory unit has a program verify mode, and erase verify mode, a compact mode and a compact verify mode.

Referring to FIG. 3, the requirement for a plurality of charge pumps for the operation of various modes of a Flash memory is shown.

As will be familiar to those skilled in that art, the foregoing voltage levels are typical. Changes in the fabricating process will cause the parameters to change from the typical values. This change in parameter values can determine the reliability during operation and can determine the speed with which the operation of the cell during the various modes can take place. In some instances, the change in parameters is intentionally performed to change the operating parameters. In any event, the change in Flash memory cell fabrication parameters can result in unacceptable operating parameters. Consequently, a need has been felt for apparatus and method to accommodate a difference in fabrication parameters in the operation of the Flash memory cell 10.

A need has therefore been felt for apparatus and an associated method having the feature of providing an improved Flash memory unit. It would be yet another feature of the apparatus and associated method to provide customized parameters to be stored in the Flash memory unit. It is a more particular feature of the apparatus and associated method invention to provide customized parameters in the Flash memory unit that relate to the parameters of the operation of the Flash memory itself. It would be a still further particular feature of the present invention to provide apparatus that permits the operation of the Flash memory to compensate for changes in the parameters of the Flash memory cells.

### SUMMARY OF THE INVENTION

The foregoing and other features are accomplished, according the present invention, by providing a normal Flash memory region and a compensation Flash memory region. The normal Flash memory region operates in the same manner as the typical Flash memory, i.e., storing information that is non-volatile. In the compensation Flash memory region a group of Flash-memory cells is provided that are especially fabricated so that the information stored therein is not available for manipulation by the user. This information is stored by the manufacturer of the memory and can only be altered by the manufacturer. Before the normal portion of the Flash memory is accessed, the compensation portion of the Flash memory is accessed. The data in the compensation portion of the Flash memory unit is used to select parameters for the operation of the normal Flash memory portion.

Other features and advantages of present invention will be more clearly understood upon reading of the following description and the accompanying drawings and the claims.

### BRIEF DESCRIPTION OF THE DRAWINGS

FIG. 1 is block diagram of a Flash memory cell according to the prior art.

FIG. 2 illustrates typical parameters of the operation of the Flash memory unit according to the prior art.

FIG. 3 illustrates the application of the voltages from a plurality of charge pumps according to the prior art.

FIG. 4 illustrates a plan view of the Flash memory unit according to the present invention.

FIG. 5 is a block diagram of the use of the compensation portion of the Flash memory to compensate for an alteration in the parameters of the Flash memory.

### DESCRIPTION OF THE PREFERRED EMBODIMENT

### 1. Detailed Description of the Figures

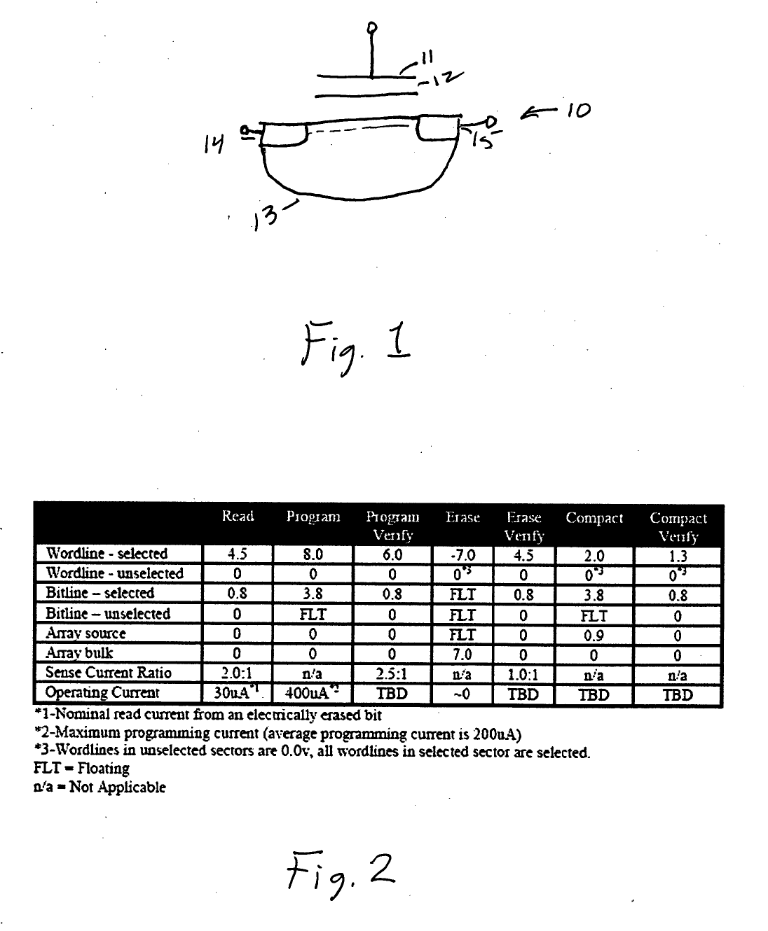

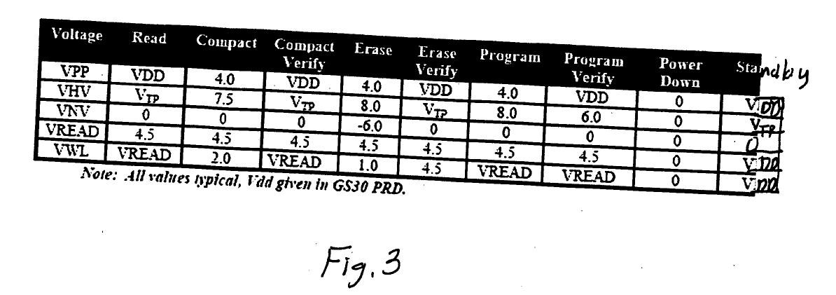

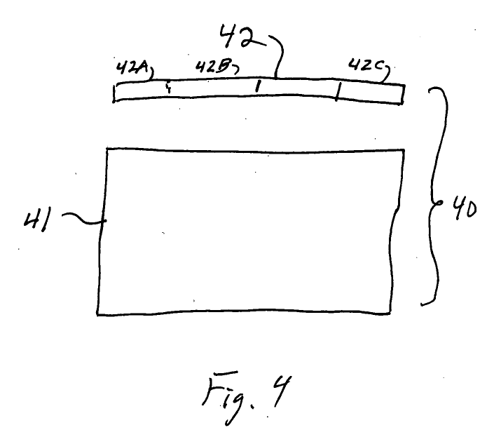

FIG. 1, FIG. 2, and FIG. 3 have been described with respect to the prior art.

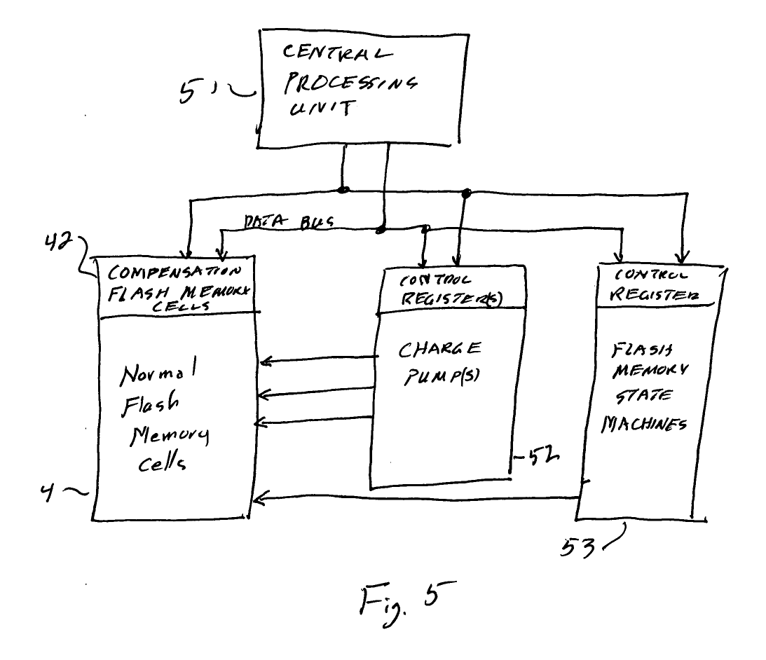

Referring next to FIG. 4, a plan view of the Flash memory according to the present invention is shown. The Flash memory of FIG. 4 has two main regions, a typical Flash memory region and a second Flash region for storing operating parameters for the interaction with the first Flash memory portion. These regions are shown in FIG. 4 as being separated. The reason for this separation is that, for the user, this second portion of the Flash memory is a read only memory. The contents of the second Flash memory portion are entered in the Flash memory unit by the manufacturer and can not be altered by the user. The contents of the second Flash memory portion are:
voltage levels for each charge pump as a function of mode 42A,
number of voltage pulses applied to a Flash memory cell along with any change in voltage level for consecutive voltage pulses 42B, the length of time of voltage pulses, and
checksum region and/or error correcting code region 42C.

The checksum is used to verify the accuracy of the storage of the operating parameters. The error-correcting code permits the reconstruction of the correct parameter when an error is detected.

Referring to FIG. 5, a block diagram of the apparatus for using the contents of the second Flash memory portion is illustrated. Before starting a program or erase operation, the processor 51 reads values from the compensation flash 42 and stores them in control registers for the charge pump 52 and the flash state machine 53. The values in these control registers control the voltage levels used during programming and erase operation, the length of pulses during operation, and the maximum number of pulses to use during the operation.

### 2. Operation of the Preferred Embodiment

The present invention provides a technique for operating Flash memory units that have been fabricated using different process conditions to operate under near optimal conditions. This optimization of the operating condition of the Flash memory is provided by controlling the parameters of operation especially the voltages for each operational mode and the number of voltage pulses, if more than one.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. A Flash memory system, the system comprising:
a Flash memory having a first and a second portion, wherein the second portion of the Flash memory stores control signals;
a plurality of voltage generators coupled to the first and second portions, the voltage generators including control registers; and
a processor, the processor providing signals to the second Flash memory portion to read the control signals and to transfer the control signals to the processor, the processor transferring the control signals to the voltage generator control registers, the voltage generators applying voltage levels determined by the control signals to the first Flash memory portion during each Flash memory mode of operation.

2. The Flash memory system as recited in claim 1 wherein the signals to the second Flash memory portion include preselected voltage levels.

3. The Flash memory unit as recited in claim 2 further comprising a state machine for controlling the first portion of the Flash memory unit, the state machine including control registers, wherein the processor initializes the state machine control registers by storing control signals therein.

4. The system as recited in claim 1 wherein the voltage generators are implemented by charge pumps.

5. The system as recited in claim 1 wherein the control bits are Flash memory system parameters determined by the manufacturing process forming the Flash memory unit.

6. The method as recited in claim 1 wherein the control bits stored in the second Flash memory portion can not be altered by a Flash memory user.

7. The method of providing for differences in operating parameters of a Flash memory system, the method comprising:
storing the operating parameters for each Flash memory system in a second portion of the Flash memory unit; and
using the operating parameters stored in the second portion of a Flash memory unit to determine the operating parameters for each mode of the first portion of the Flash memory.

8. The method as recited in claim 7 further comprising the step of determining the operating parameters from the process used in manufacturing the Flash memory system.

9. The method as recited in claim 7 further comprising preventing a user of the Flash memory system from altering the operating parameters stored in the second portion of the Flash memory system.

10. The method as recited in claim 7 further comprising determining the operating parameters stored in the second portion of the Flash memory system.

11. The method as recited in claim 10 further comprising determining output voltages of charge pumps from the operating parameters.

12. In a data processing unit, a Flash memory system, the system comprising:
a first Flash memory portion; and
a second Flash memory portion, the second Flash memory portion storing operating parameters for modes of operation of the first Flash memory portion.

13. The system as recited in claim 12 wherein the operating parameters stored in the second Flash memory portion are a result of the manufacturing process of the first Flash memory portion.

14. The system as recited in claim 12 wherein the operating parameters are determined by the manufacturing process of the Flash memory system.

15. The system as recited in claim 12 wherein the operating parameters can not be altered by a user of the data processing unit.

16. The system as recited in claim 12 wherein the data processing unit includes a plurality of charge pumps coupled to the Flash memory system, the operating parameters determining the voltages applied to the second Flash memory portion during each mode of operation.

17. The system as recited in claim 16 wherein the data processing system includes a processor, the processor reading the operating parameters from the first Flash memory portion, the processor applying control signals to the charge pumps based on the operating parameters.

18. The system as recited in claim 12 further comprising:
a plurality of voltage generators for applying voltage waveforms to the Flash memory unit; and
a state machine, the state machine providing command signals to the second Flash memory portion to transfer control signals stored therein to the voltage generators, the control signals applying predetermined voltage waveforms to the first Flash memory portion during Flash memory unit operations.

19. The system as recited in claim 18, the state machine control registers, wherein the control registers are initialized by the state machine transferring control signals from the second Flash memory portion.
